(19) United States
(12) Patent Application Publication
(10) Pub. No.: US 2008/0032109 A1
(43) Pub. Date: Feb. 7, 2008

(54) Method for Coating Blanks for the Production of Printed Circuit Boards (Pcb)

(76) Inventors: Gunther Leising, Graz (AT); Johannes Stahr, Bruck an der Mur (AT); Fritz Haring, Bruck an der Mur (AT); Ping Zhao, Wien (AT); Gerhard Nauer, Langenzersdorf (AT)

Correspondence Address: LADAS & PARRY, 26 WEST 61ST STREET, NEW YORK, NY, 10023, US

(21) Appl. No.: 10/556,514

(22) PCT Filed: May 13, 2004
(86) PCT No.: PCT/AT04/00168

§ 371 Date: Apr. 12, 2007

(30) Foreign Application Priority Data
May 13, 2003 (AT) A 726/2003

(51) Int. Cl. H05K 3/00

(52) U.S. Cl. 428/220; 427/299; 427/402; 428/411.1; 428/446; 428/704

(57) ABSTRACT

The invention relates to a PCB blank comprising a protective film which is resistant to acid and which is made of at least two layers which are chemically linked to each other underneath each other and/or are linked to the metal surface of the PCB blank. The invention also relates to a method for coating a PCB blank with a protective film which is resistant to acid and which is made of at least two layers.

The present invention relates to a method for coating blanks for the production of printed circuit boards (PCBs) as well as blanks coated in this manner for the production of PCBs.

In the production of plated-through, printed circuit boards of copper it is necessary to accurately print a circuit to both surfaces of the blank for the printed circuit board and to connect the circuits on both surfaces at the predetermined, required positions. As the blank for PCBs, in particular epoxy resin-impregnated glass fiber fabric having a copper coating on one or both sides thereof is considered, and hereinafter generally any metal-coated carrier will be subsumed by the term PCB blank. As the metals, particularly platinum, titanium, silver, gold, nickel, zinc, iron or alloys thereof, alloys such as steel and brass, yet also metal oxides, such as copper oxide, aluminum oxide and iron oxide are under consideration.

In the prior art, several production methods are already known, such as, e.g., the hole-filling method and the electrolytic solder plating method. The hole-filling method has become most widely used in the production of plated-through copper-PCBs. After many method steps (such as drilling, electroplating, photo and etching processes), such as described in EP 0364132 A1, e.g., a plated-through printed circuit board of copper is obtained. The electrolytic solder plating method is suitable insofar as it enables the production of a highly reliable, plated-through printed circuit board, yet it has the disadvantage that it requires long production times, high production costs and a lot of chemical treatment, causing pollution of the environment and great expenditures to counteract such environmental pollution. Therefore, it has become necessary to provide a method with a more rapid production and lower costs.

Since 1986 research has been conducted in this field, and a number of patents have been published which relate to improvements in the production of PCBs. Extensive research on this basis has led to a method, wherein by immersion of the copper-plated, laminated blank for a circuit board in an aqueous solution of a salt of an alkyl imidazole compound, a complex was formed from the alkyl imidazole compound (an alkyl group having from 5 to 21 carbon atoms) with copper or a copper alloy as a resist film for alkali, which film can be used for the method of producing plated-through printed circuit boards (cf. e.g. U.S. Pat. No. 4,622,097, DE-19944908 and JP-63005591). The dissolved alkyl imidazole compound is highly reactive with copper, and by this an imidazole layer is formed on the surface of the copper. It has been known that by the effect of the hydrogen bond among the long-chain alkyl imidazole molecules and due to the Van-der-Waals forces, the alkyl imidazole molecules present in the aqueous treatment solution further deposit on the surface of the coating, thereby further increasing the coating thickness. The compound is cheaper, more reliable and easier to remove than the photo-sensitive polymer resist films known in the prior art, it is resistant to alkaline etching and therefore protects the copper-plated parts of the blank against an etching solution. Thus, this method does provide a simple method for producing a plated-through PCB, yet it has disadvantages insofar as the protective film can only resist alkaline etching solutions which are not suitable for the recently used acidic etching methods. Therefore, further research has been focused on the development of an acid etching resist film which is suitable for the current PCB production. The acid resist film can be prepared from an organic compound (oligomer or polymer of low molecular weight, and combinations of both), which both contain a hydrophilic group and a hydrophobic portion. The hydrophilic group is a polar group with high affinity or reactivity relative to copper. The hydrophobic portion has a long alkyl group of from 5 to 21 carbon atoms and has water-resistant properties.

For the production of blocking layers having a thickness of less than 100 Angstrom, self-aggregating monolayers (SAMs) provide a flexible method for forming tightly packed, crystalline coatings, in which the oriented carbohydrate chains are chemically bound to the subjacent metal. The most characterized systems of SAMs are n-alkanethiols CH₃(CH₂)ₙ₋₁SH, organosilane CH₃(CH₂)ₙ₋₁SiCl₃ and organophosphoric acids CH₃(CH₂)ₙ₋₁PO₃H₂ (where n=4, 5, 8, 12, 16, 18, 20, 22 and 29) on copper. Due to their ability of forming tightly packed and homogeneous films on metallic carriers, SAMs derived from these organic molecules are suitable for blocking the electron transfer or as corrosion inhibitors (they restrict the diffusion of oxygen, water and aqueous ions). Cross-linked SAMs yield more robust films with improved grades of protection. In comparison with polymer films, SAMs provide more flexible systems with simpler processing for the formation of partially crystalline blocking films on copper. The formation of blocking films is the result of a simple chemical adsorption process, and thin, uniform, conformable films are generated. In practice, the use of strong chemical adsorption of alkanethiols on copper has been widely applied. The preference for the long-chained adsorbates has been explained by greater cohesive interactions between long alkyl chains in the monolayer. By the formation of Cu—S bonds, the thiols are directly chemically bound to the metal surface. The formation is highly exothermal and provides a great impetus for adsorption. Initial adsorption is rapid, with the consequence that approximately 90% of the final monolayer cover is obtained within seconds. After having been adsorbed to the surface, the molecules undergo a slower organizing procedure which may last from several minutes to several days, depending on the chemical structure of the derivatives used. Several factors influence the formation and packing density of the monolayers, such as the type and unevenness of the carrier, the solvent used, the type of adsorbate, temperature, and the concentration of the adsorbate. Cleanness and crystallinity of the carrier also play a decisive role in determining the compactness which frequently is quantitatively evaluated by the pinhole distribution (i.e. the distribution of minute holes). Prior to the monolayer formation, most carriers require rigorous cleaning treatments and pre-treatment of the carrier. A highly diluted solution will result in an organized monolayer, whereas a high concentration and a long time will be favorable for multilayer formation (Kim, 1993). Chain length is a further important parameter, since a dense monolayer can be obtained by controlling the chain length so as to achieve the crystalline structure (Porter, 1987). As a consequence of π-π-interactions, phenyl and biphenyl systems also exhibit good packing, yet they are less stable than that of the long-chain adsorbates (Aslam, 2001). Preference for long-chain adsorbates is greater for the adsorption from ethanol than for the adsorption from hexanol solvent (Rowe, 1994). The effects of solvents on the self-aggregating procedure show that the solvatizing energetics are capable of moderating the dispersion forces in the monolayer and drive the preference adsorption of long-chain adsorbates. Although the molecules of the adsorbates are chemically adsorbed on the carrier, there occurs no substantial loss of SAM, as long as the film is not heated to more than 230° C.

(a) Organothiols

Blackman et al. (Blackman, 1957) have reported that long-chain alkanethiols are effective promoters of drop-wise condensation on the copper surface of condenser tubes. These compounds have been found to be effective inhibitors of copper corrosion (Fujii, 1966). Whitesides et al. have found that Angstrom degree changes in the thickness of the monolayer lead to easily recognizable differences in the oxidation rates of copper and adsorbed thiolate (Laibinis, 1992). SAMs formed of short-chain thiols (n <12) are less crystal-line and have substantially poorer blocking properties than those of the long-chain analogs (n >16). SAMs formed of long-chain adsorbates are superior to the shorter-chain analogs in retaining their structure and properties as a consequence of the Van-der-Waals interactions. The ability of a film to retain its blocking properties exponentially scales with the chain length of the n-alkanethiol, wherein five additional methylenes in the chain yield films which are twice as effective with regard to retaining their blocking properties. Electrochemical measurements of heterogeneous electron transfer rates and differential capacitance indicate that the long-chain monolayers are free from pinholes, provide substantial barriers relative to electron transfer and are highly resistant to ion penetration (Tao, 1994).

Long-chain alkanethiols (HS(CH₂)ₙX) with polar and non-polar terminal groups can adsorb to the surface of freshly produced Cu surfaces from solutions and form an oriented monolayer (Laibinis, 1992). ω-terminated alkanethiolate monolayers are composed of trans-elongated chains with orientation to copper, which are close to the perpendicular relative to the surface. Such alkanethiolate monolayers on copper have varying wettability as a function of high-grade hydrophilic surfaces (terminated by X=—OH, —CONH₂, —COOH etc.) and hydrophobic surfaces (terminated by X=—CH₃, —CH=CH₂, —OCH₃, —CO₂CH₃ etc.). Due to a self-aggregating process, these ω-substituted straight-chain thiols are capable of producing dense, highly oriented and organized monolayer films on gold surfaces. A variation of the terminal functional group of the chain has comparatively little effect on the structure of the film in the region of the carbohydrate chains. Moreover, the exchange of the end groups by carboxylic acid groups gives rise to a much stronger interaction at the chain ends by hydrogen bonds between the end groups and solvent and between the end groups themselves. Shorter-chain thiols with bulky end groups frequently lead to coverage with a lower density and distorted packing.

b) Organosilanes

Self-aggregating monolayers of long-chain organosilane compounds (R—SiCl₃, R—Si(OCH₃)₃, R=alkyl group with >10 carbon atoms) on hydroxylated surfaces have been the target of numerous studies ever since their discovery by Sagiv et al. in 1980 (Sagiv, 1980). The result of all these studies has been a general agreement that complete monolayers of these compounds constitute highly organized, crystalline-like phases in which the carbohydrate chains are almost perpendicularly oriented relative to the surface on a plurality of different carriers, including natural silicon, mica, germanium, zinc, selenide, glass, aliminum oxide, copper and gold. Alkyl siloxane monolayers are formed from alkyl silanole precursors on a plurality of OH-terminated surfaces. The surface OH groups function as active participants in the nucleation and the growth of these films (Rye, 1997). The surface concentration of hydroxyl groups which serve as centers of nucleation and as anchoring points in the film forming process, may have an extended influence on the growing process and the film structure of the submonolayer. The specific conditions of the film generation, such as the water content of the adsorbate solution, the solvent, the precursor concentration or the type and pre-treatment of the carrier must be considered. The structure of the submonolayer films is highly dependent on some of these parameters. The water concentration on the carrier surface influences the rate of the surface polymerization and the surface diffusion of the film molecules. The size of the primary isles deposited on the carrier will also depend on the degree of polymerization of silanol precursors in the adsorbate solution which in turn will depend on a plurality of factors, including the water content, the reaction time or the type of solvent used.

(c) Combination of Organothiols and Organosilanes for Corrosion Protection

The properties of the corrosion protection layers have been improved by chemical modification of the self-aggregating layer with various coupling agents. A self-aggregating monolayer of 11-mercapto-1-indecanole (MUO) (Itoh, 1995), chemically adsorbed on an oxide-free copper surface, was modified by alkyl trichlorosilanes C₁₈H₃₇SiCl₃. The modified MUO layer is hydrolyzed with water, followed by spontaneous polymerization, so as to form a uniform polymer mono-layer on the Cu surface. This film was significantly protective against aqueous and atmospheric corrosion of copper (Ishibashi, 1996). It is also extended by modification of the 11-mercapto-1-undecanole, with 1,2-bis-(trichlorosilyl)-ethane (BTCSE) so as to form a two-dimensional polymer structure on copper, and subsequent treatment with an alkyl trichlorosilane, so as to obtain further improvements in protection (Haneda, 1997). The protective action of the BTCSE and C₁₈H₃₇SiCl₃ modified MUO monolayer at 24 h copper corrosion in an aerated 0.5M Na₂SO₄ was 98.9%. The two-fold modified layer was clearly water-resistant and highly protective against atmospheric corrosion of copper.

(d) SAM of Alkane Phosphoric Acids

Alkane phosphoric acids are coatings for natural oxide surfaces of metals or alloys, such as tin, iron, steel, aluminum, copper (Alsten, 1999) and various flat oxide carriers (TiO₂, Nb₂O and Al₂O₃) . The films were produced by self-aggregation from a heptane-propan-2-ol solution. Contact angle measurements and absorption near edge X-ray fine-structure spectroscopy indicate that these layers were formed similarly to the thiolgold systems and provide access to possible applications in the field of corrosion protection. Various methods have been developed for connecting self-aggregating monolayers among themselves in the third dimension. One of the most successful applications includes the sequential adsorption of the components of tetravalent metal phosphonate salts from aqueous and non-aqueous solutions (Umemura, 1992). Films produced in this manner are structurally analogous to layered, metallo-organic compounds in which the metal oxygen phosphorus network is kept together by strong ionic and covalent bonds. While the tetravalent metal phosphonates are the best known ones of these materials, some layered phosphonate salts of bivalent and trivalent elements have recently been described. Thin films of bivalent metal (Zn and Cu) alkanbiphosphonates have been produced on gold surfaces and modified with (4-mercaptobutyl)phosphoric acid (Hong, 1991) by alternating immersion in ethanolic solutions or percholate salt and H₂O₃P(CH₂)ₙPO₃H₂, n=8,10,12 and 14 (Yang, 1993). The growth of each layer is remarkably quick. Well organized multilayers can be deposited with 10 minute adsorption steps, and films of 100 layer thickness are readily produced.

(e) Polymer Coating for Corrosion Protection

The polymer multilayers are highly cross-linked and much thicker than an individual SAM. Polymer coatings with high degrees of crystallinity and dense packing are more effective in reducing the diffusion of water and have good mechanical properties (thermal, shrinkage, impact, tear resistance and good elongation capacity, adhesion capacity and processability), which are suitable for industrial production. In practice, polymer coatings, such as polyimides (Bellucci, 1991) and polystyrene (Kurbanova, 1997) are often used to protect metals against corrosion. The polymer layer functions as a thick, hydrophobic barrier which prevents the transport of water and other corrosive agents. The polymer can readily be prepared as a thin film by spin coating methods (Stange, 1992). A combination of organothiol SAM and polystyrene polymer has been examined (Jennings, 1999). Atomic force microscopy (AFM) images of the films revealed a complete film without any signs of defects. A 40 μm cast film contains CO₂-H-modified poly(vinyl alcohol) and exhibits good acid resistance. When converted into its salt form by the addition of NaOH, it is readily soluble in water (JP-10/060207 A). A carboxylic-acid terminated SAM with a polymer multilayer which contained poly(ethylene imine) and poly(octadecen-alt-maleic acid anhydride) (POMA Mw. 30,000) or poly(styrene alt maleic acid anhydride) (PSMA) as an effective etching protection (KI-based commercial gold etch) gave the best result (Huck, 1999). The demand for pinhole-free coatings has led to a new coating strategy using conductive polymers as the main component. The first documented findings of a corrosion protection of steel by polyaniline were reported in 1981. Since then, numerous documents regarding the corrosion protection of soft steel, special steel (Ren, 1992) iron (Beck, 1994), titanium, copper (Brusic, 1997) and aluminum (Racicot, 1997) have been published.

It is now an object of the present invention to provide PCB blanks departing from the initially mentioned prior art, wherein the metal surface of the blank is coated with an acid-resistant protective film. A further object consists in providing a method for coating PCB blanks with such an acid-resistant protective film.

According to the present invention, the acid-resistance protective film of a PCB blank is comprised of at least 2 layers which are chemically bound to each other or which are chemically bound to the metallic surface of the PCB blank. By the chemical bond of both, the first monolayer with the metallic surface of the PCB blank, and of any further monolayer with the subjacent monolayer, it is possible to provide extremely thin protective films by avoiding pinholes due to the topography of the metallic surface of the blank, or local wetting problems, respectively.

Preferably, the protective film of the PCB blank has a thickness of less than 20 μm, more preferred, less than 10 μm, and most preferred, less than 4 μm. By such thin protective film coats, particularly the problem of channel formation during the production of the PCBs can be avoided. In short, this problem consists in that in the mostly laser-supported PCB production, the width of the track which can be burnt into the surface of the coated PCB blank will depend on the thickness of the protective film insofar as a ratio of 1:1 (thickness of the protective film plus thickness of the metal coating of the blank:width of track) shall not be fallen below. At a thickness of approximately 30 μm at present achievable by conventional protective films in the prior art, and a thickness of the metal coating of the blank of approximately 20 μm, this means that a track width of the laser beam of approximately 50 μm shall not be fallen below, since otherwise the metallic copper still present in the track cannot be completely removed by the etching solution used. Since by the present invention, a substantially slighter thickness of the protective film can be achieved, also a substantial reduction in the track width of the laser beam is possible, whereby, as a further consequence, also a higher packing density of the structural elements on the finished PCB is possible.

According to a preferred embodiment of the present invention, the at least 2 layers of the protective film are each formed by a compound of the general formula

W(R)Y

wherein

W represents —SH, —Si(X)₃, —Si(OR)X₂, —Si(OR)₂X, —Si(OR)₃, —COOH, —PO₃H₂;

R represents alkyl (—CₙH₂ₙ—), optionally substituted with one or more X and/or OH and straight-chain, branched or cyclic with straight-chain alkyl portion, or an aromatic group, preferably substituted by one or more X and/or —OH, and n=2 to 32,

X represents fluorine, chlorine, bromine or iodine, and

Y represents —OH, COOH, —PO₃H₂.

The invention is based on the knowledge that due to the functional group W, the above-indicated classes of compounds have a high degree of adsorptive force with regard to metallic surfaces and a covalent bond is formed during the adsorption. Conventional pure metals, such as copper, in particular also the elements of the sub-group of the periodic table (e.g. platinum, titanium, silver, gold, nickel, zinc, iron or alloys thereof), alloys of steel and brass, yet also metal oxides, such as copper oxide, aluminum oxide and iron oxide can be used as metal coatings of the PCB blanks. Due to the high adsorption force of the W-functional group in relation to the metallic surface, it is possible to deposit a monomolecular coating (monolayer) on the metallic surface. By this, only a slight amount of adhering substance is required, which is cost-effective. Moreover, by the chemical bond between the monolayers, and between the first monolayer and the metallic surface of the PCB blank, respectively, wetting problems are overcome.

It has been shown that it is particularly advantageous that for the purpose of adherance on the metallic carriers, the adhering substance has as W a thiol (—SH), silane (—Si(Cl)₃, —Si (OR)₂Cl, —Si (OR) Cl₂, —Si(OR)₃), organophosphoric acid (—PO₃H₂) or organocarboxylic acid (—COOH) group, which can form a covalent bond to the metal surface (such as, e.g., Cu—S). Furthermore, it has been found that particularly with these compounds, an adsorption relative to the metallic surface will occur which is largely spontaneous, producing a monomolecular coating on the metallic surface.

As further structural component of the class of the compounds according to the invention, R (alkyl residue, halogenated alkyl residue, alkyl residue or halogenated alkyl residue with hydroxyl group in the chain, or aromatic group, respectively) functions as a spacer.

Particularly preferably, n in the above-indicated general formula means an integer of from 10 to 22. Depending on the magnitude of n, the chain length of R and, thus, in a certain way also the thickness of the monolayer can be varied, and moreover, in the indicated range of n, there is the advantage of the possibility of an optional use of a conventional solvent.

R may also be an aromatic unit and preferably has halogen and/or hydroxyl substituents in the aromatic system. Depending on the type of substituent, they may in turn have an influence on the bond to the metallic surface or on the further coating of the monofilm. As a consequence, the film may form an optimum, dense, hydrophobic space so as to prevent etching agents from reacting with the metal surface.

As has already been mentioned, Y preferably represents —OH, —COOH or —PO₃H₂ and therefore, in case of a homo-coating, may readily react with the functionality group W of the, or of a further compound W(R)Y, respectively, so as to form a multilayer. For instance, a hydroxyl group reacts with a silane molecule, whereby a covalent bond is formed (an O—Si—O bond, e.g.).

According to a further preferred embodiment of the present invention, the first layer is formed by a compound of the general formula

W(R)Y

wherein W, R, X, n and Y are as defined above, on which layer at least one further layer is deposited which is formed by a compound of the general formula

Z(R)L

wherein:

Z represents Si(OR₂)₂X, —Si(OR₂)X₂, —SiX₃, —PO₃H₂,

L represents —OH, —COOH, —OCH₂, —OR, —CH₃, —CH═CH₂, —COOCH₃, —COOR, —CONH₂, and

R, X and n are as defined above.

L denotes a terminal group which is capable of changing the surface characteristic of the multilayer from hydrophobic to hydrophilic or from hydrophilic to hydrophobic. Examples thereof are highly hydrophilic surfaces (terminated by L=—OH, —CONH₂, —COOH etc.) and hydrophobic surfaces (terminated by L=—CH₃, —CH=CH₂, —OCH₃, —CO₂CH₃ etc.).

Particularly preferably n in the above-indicated general formula is each independently an integer of from 10 to 22.

As the top or cover layer, respectively, the acid-resistant protective film of a PCB blank preferably comprises an organo-soluble or alkali-soluble polymer which has selectively been applied to the surface of the multilayer. The coating of the polymer on the inventive protective film protects the functionality L. In this manner, a sufficient adhesion is generated between polymer and multilayer. The polymer film has as its function to improve the mechanical properties of the multilayer, such as the thermal, shrinkage, impact and tearing resistance, as well as the adhesion capacity and processability. A number of polymers can be used for this. For the alkali-soluble polymer, it is composed of acrylic acid, sulfonic acid, maleic acid and their ester copolymers with styrene, dimethylsilane, styrole, olefin, isobutylene, vinyl, ethene, imide, methylstyrene, acrylamido, vinylether, ethylene-covinyl acetate, ethylene etc. The typical alkali-soluble polyemer resins are based on a polymer which contains an —SO₃H, —COOH— group, or its alkali metal salt or its ester, e.g. poly-(dimethylsiloxane)-graft-poly-acrylate, poly(acrylic acid), poly(sodium-4-styrene sulfonate), poly(4-styrene-sulfonic acid co-maleic acid), poly(styrene/α-methylstyrene/acrylic acid), poly/dimethylsilane)-monomethacrylate, poly(2-acrylamido-2-methyl-1-propanesulfonic acid, poly(2-acrylamido-2-2-methyl-1-propane-sulfonic acid-co-styrene), poly (styrene-alt-maleic acid), poly-(methyl-vinylether-alt-maleic acid), poly-(sodium-methacrylic acid), poly-(maleic acid-co-olefin)-sodium, poly-(isobutylene-co-maleic acid)sodium, poly-(ethylene-co-vinylacetate-co-methacrylic acid), poly-(ethylene-co-methacrylic acid), poly-(ethylene-co-acrylic acid)-sodium, poly-(ethylene-co-acrylic acid-methylester-co-acrylic acid), poly-(ethylene-co-acrylic acid), poly-(vinylsulfonic acid-sodium), etc.

The present invention further relates to a method for coating PCB blanks with an acid-resistant protective film, comprising the following steps:
a) optionally pre-cleaning, drying, activating and/or surface treating the PCB blank,
b) forming a first monolayer on the metal surface of the PCB blank by applying a compound of the general formula

W(R)Y

wherein

W represents —SH, —Si(X)₃, —Si(OR)X₂, —Si(OR)₂X, —Si(OR)₃, —COOH, —PO₃H₂;

R represents alkyl (—CₙH₂ₙ—), optionally substituted with one or more X and/or OH and straight-chain, branched or cyclic with straight-chain alkyl portion, or an aromatic group, preferably substituted by one or more X and/or —OH, and n=2 to 32,

X represents fluorine, chlorine, bromine or iodine, and

Y represents —OH, COOH, —PO₃H₂.
c) forming at least one further monolayer on the first monolayer of the PCB blank by applying either
c)1) a compound of the general formula

W(R)Y

wherein W, R, X, n and Y are as defined above, or
c)2) a compound of the general formula

Z(R)L

wherein

Z represents Si(OR₂)₂X, —Si(OR₂)X₂, —SiX₃, —PO₃H₂,

L represents —OH, —COOH, —OCH₂, —OR, —CH₃, —CH═CH₂, —COOCH₃, —COOR, —CONH₂, and

R, X and n are as defined above,
d) optionally repeating step c) several times, and
e) optionally forming a cover layer from an organo-soluble or alkali-soluble polymer on the uppermost monolayer of the PCB blank.

In the above-indicated general formulae, n preferably is each independently an integer of from 10 to 22.

According to a preferred embodiment of the method according to the invention, the compounds for providing the individual monolayers are applied in solution.

Preferably, the compounds for providing the individual monolayers are applied by immersing the PCB blank in corresponding solutions of the individual compounds. By “immersing”, in this context any process is to be understood by which the PCB blank is contacted with the corresponding solutions of the individual compounds, i.e. by directly guiding them through the solution(s), by meniscus-coating or by roller-coating, e.g.

In the following, the individual steps of the method according to the invention will be explained in more detail:

a) Carrier Treatment

The condition of the metallic surface of the PCB blank can influence the molecular organization, monolayer coverage and the thickness of an adsorbed monolayer. Optionally, the blanks may, e.g., be pre-cleaned by a chemical process (Ingo-pure, NPS and HCl) and then dried in hot air. Subsequently, the blanks may be immersed e.g. in isopropanol for surface activation and rinsed with water. After this, if desired, also suitable surface treatment methods may be applied, such as chemical etching by using an inorganic acid (HCl, HNO₃, H₃PO₄, H₃BO₃, H₂SO₄, HClO₄ etc.), polishing and cathodic reduction for polishing the blank. While HCl-etching will yield an oxide-free surface, Cl⁻ in HCl may be adsorbed on the copper surface during said etching, which may reduce the adsorption capacity of the surface for forming the monolayer and may lead to corrosion forming on the cleaned surface. If the metallic surface of the blank consists of copper, e.g., and etching is performed in an oxidizing acid, such as nitric acid, an oxide copper surface may be formed which seems to promote the special adsorption of organosilanes. By phosphoric acid or boric acid (non-oxidizing acids), the upper layer of the copper atoms was removed from the copper surface, and the cleaned surface may be kept under air for a comparatively long period of time without any significant oxidation. Using polishing and cathodic reduction (66% orthophosphoric acid for 10 s at a cathodic value of between 1.8 and 2.4 V vis-a-vis a platinum counter electrode), no homogeneous morphology could be obtained. Therefore, the nitric acid (4N), phosphoric acid (20% v/v), ortho-phosphoric acid (66% v/v) and boric acid (20% v/v) etching preferably were used for a certain time (from 5 min to several hours, typically 5 min) at room temperature, followed by rinsing in water and drying in nitrogen or in a furnace at 60-100° C., so as to form a fresh, active and hydrophilic surface which greatly promotes the chemical adsorption of alkanethiol, alkanesilane and alkanephosphoric acid.

(b) Forming a first monolayer in the example of organothiol:

After washing twice with anhydrous ethanol, the copper-plated PCB blank is immersed in an ethanol solution of thiols at room temperature for a certain time (from 1 min to several days, typically from 5 to 15 min), so as to complete the chemical adsorption of the thiol on the copper surface. An excess of the thiol can be removed from the carrier surface by rinsing the surface with ethanol, whereupon the PCB blank is dried in a furnace (from 30-150° C., typically at 80° C.). The organothiols used, e.g., when carrying out the monolayer adsorption are based on the structure:

W(R)Y

having the meanings set out above, e.g., 1-dodecan-thiol, 1-octadecanethiol, 3-mercapto-1,2-propanediol; 4-mercaptophenole 6-mercapto-1-hexanol, 3-mercapto-1-propanol, 11-mercapto-1-undecol, 2-mercaptoethanol, 4-mercapto-1-butanol or 4-mercaptobutyl-phosphoric acid.

(c) Forming a second monolayer (as above, or in the example of organosilane):

For building the second monolayer on the SAMs of thiols, either the above method is repeated for forming a second monolayer, or the mono-coated PCB blank obtained in the above method is immersed at room temperature in a cyclohexane solution of organosilanes, e.g., for from 1 min to several days (typically, 5 to 15 min). Further solvents usable in the organosilane application are, e.g. toluene, a mixture of hexadecancarbon tetrachloride-chloroform 80:12:8, n-hexane, tetrahydrofuran, etc. To remove an excess of organosilanes, the surface may then be thoroughly rinsed with chloroform, followed by placing the thus treated PCB blank in a furnace (temperature from 50° C. to 150° C. for 1 min to several hours) so as to remove the solvent and to harden the multilayer, whereby also a cross-linking may be effected in the multilayer. Subsequently, the PCB blanks are placed at normal temperature into a high humidity box (more than 85%) for wet hardening (from several minutes to several days). Wet hardening is suitable for the further conversion of Si—Cl bonds to Si—O bonds and for uniform network formation in the multilayer.

(d) Formation of a multi-coating

As has already been mentioned, the compounds for multilayer formation are based on the above-indicated compound of the general formula

W(R)Y

with the meanings indicated above, and optionally on a compound of the general formula

Z (R) L

with the meanings indicated as above, such as, e.g., methyl-trichlorosilane, ethyl-trichlorosilane, propyltrichlorosilane, butyl-trichlorosilane, isobutyl-trichlorosilane, pentyl-trichlorosilane, hexyl-trichlorosilane, octyl-trichlorosilane, Decyltrichlorosilane, decylmethyl-dichlorosilane, dodecyltrichlorosilane, dodecylmethyl-dichlorosilane, octadecyl-methyl-dichlorosilane, octadecyl-trichlorosilane, benzyl-trichlorosilane, undecyl-trichlorosilane, 2-(bi-cycloheptenyl)-dimethylchlorosilane, 2-(bicycloheptenyl)-trichlorosilane, n-butyl-dimethylchlorosilane, n-butylmethyl-dichlorosilane, p-(t-butyl)-phenethyldimethylchlorosilane, p-(t-butyl)-phenethyl-trichlorosilane, 4-chlorobutyl-dimethylchlorosilane, 13-(chloro-dimethylsilylmethyl)-heptacosane, ((chloro-methyl)-phenylethyl)-dimethylchlorosilane, ((chloro-methyl)-phenylethyl)-methyl-dichlorosilane, ((chloromethyl)-phenylethyl)-trichlorosilane, 3-chloropropyl-trichlorosilane, cyclohexyl-trichlorosilane, docosylmethyl-dichlorosilane, docosyl-trichlorosilane, eicosyl-trichlorosilane-docosyltrichlorosilane-mixture, (heptadecafluoro-1,1,2,2-tetrahydrodecyl)-trichlorosilane, (3-heptafluoroisopropoxy)-propyl-trichlorosilane, Hexadecyl-trichlorosilane, 7-octenyltrichlorosilane, pentafluorophenylpropyl-trichlorosilane, phenethyl-trichlorosilane, 3-phenoxypropyl trichlorosilane, triacontyltrichlorosilane, 13-(trichlorosilylmethyl)-heptacosane, (tridecafluoro-1,1,2,2-tetrahydrooctyl)-trichlorosilane, (3,3,3-trifluoropropyl)-trichlorsilane etc.. The multilayer formation can be provided by repeating steps (b) and/or (c) in any desired number.

(e) Polymer coating:

Sometimes the fault density of SAMs used as etching-resistant films is too high for allowing such coated PCB blanks to be directly used in the industrial production of high-resolution electronic appliances. By forming a multilayer on the PCB blank, tightly packed, homogeneous films can be produced, yet these films often lack good mechanical properties. For the industrial mass production it is suitable to additionally provide a very thin polymer layer as a cover layer so as to protect the multilayer.

For this purpose, the PCB blank provided with the multilayer is treated with a polymer base solution. This treatment aims at

(1) converting the possibly remaining Si—Cl bonds into Si—OH, a silanol group, so that cross-linking may occur between the monolayers, and

(2) providing a thin polymer film as a cover film on the PCB blank, which cover film is effective in reducing the diffusion of water and has good mechanical properties (thermal, shrinkage, impact, tear resistance and a good elongation capacity, adhesion capacity and processability) thus making it suitable for industrial production. After the coating with the polymer, the PCB blank will then be dried at 50-150° C. (typically, 120° C.) for 5 to 30 minutes (typically, 15 min) in a furnace.

The typical alkali-soluble polymer resins are based on a polymer which contains an —SO₃H or —COOH group, or its alkali metal salt or its ester, e.g. poly-(dimethyl-siloxane)-graft-polyacrylate, poly-(acrylic acid), poly-(sodium-4-styrenesulfonate), poly-(4-styrenesulfonic acid-co-maleic acid), poly-(styrene/α-methylstyrene/acrylic acid), poly-(dimethylsilane)-monomethacrylate, poly-(2-acrylamido-2-methyl-1-propan-esulfonic acid), poly-(2-acrylamido-2-2-methyl-1-propanesulfonic acid-co-styrene), Poly-(styrene-alt-maleic acid), poly-(methyl-vinylether-alt-maleic acid), poly-(sodium-methacrylic acid), poly-(maleic acid-co-olefin)-sodium, poly-(isobutylene-co-maleic acid)-sodium, poly-(ethylene-co-vinylacetate-co-methacrylic acid), poly-(ethylene-co-methacrylic acid), poly-(ethylene-co-acrylic acid)-sodium, poly-(ethylene-co-acrylic acid-methylester-co-acrylic acid), poly-(ethyl-ene-co-acrylic acid), poly-(vinylsulfonic acid-sodium), etc.

In order to obtain a good adherence between the multilayer and the polymer layer, the principle of the hydrophobic-hydrophobic or hydrophilic-hydrophilic combination should be observed. It is assumed from the surface active agents or specific interactions between the polymers that they will reduce the surface tension and thereby improve the surface adhesion for the efficient transfer of stress from one phase to the other phase. These specific interactions include hydrogen bonding, the formation of charge exchange complexes, ion-dipole and ion-ion interactions.

In a typical PCB production method, the acid-resistant protective layer at first is coated on the copper-plated PCB blank, and then it is patterned by a CO₂ or a UV laser under destruction so as to form a special configuration. The undesired copper is then etched out at the respective, protection-layer-free sites by HCl-CuCl-CuCl₂ solution. There remains the problem of entirely removing the remaining acid-resistant protective layer. The detaching procedure includes both polymer detachment as well as SAMs detachment.

Polymer detachment: The polymer used for this purpose is alkali-soluble or organically soluble and therefore can readily be separated by means of the corresponding solutions, or solvents, respectively.

Multilayer-detachment: The problem which remains is how to be able to detach the individual monolayers again. At first, the SAMs are chemically bonded to the carrier, and the bonds should break either by chemical methods (hydrolysis, oxidation) or by photo-methods (photodegradation). Secondly, the SAM film is highly hydrophobic. It is only soluble in organic solvents. ODS submonolayer which are adsorbed on Cu carriers are subjected to UV ozone oxidation (UV/ozone can be produced by a low pressure mercury quartz lamp 185 or/and 254 nm), leaving behind the two-dimensional cross-linked Si—O network of the siloxane monolayer, e.g.. The SiO₂ monolayer will then be removed by means of a 1% (HF:H₂O) solution. Photo-oxidation of RS to RSO₃ is too slow to be convenient, and the rate of this reaction can be accelerated by transition metal cations. Alkane-sulfonates which result from the photo-oxidation are only weakly bonded to copper carriers and thus can be readily removed from their surface. The photo-oxidation process using a low pressure mercury quartz lamp is only used in the laboratory for small sample treatment and has only limited suitability for industrial PCB methods. For oxidation detachment methods, there additionally exists the popular composition H₂O₂/HCl, H₂O₂/HF, CrO₃/H₂O₂, Piraha (H₂SO₄/H₂O₂) 4:1, Piraha/HF, H₂SO₄ and peroxy-disulfonic acid having the numerous disadvantages such as flammability, risk of explosion, toxicity, volatility, smell, instability at higher process temperatures. Moreover, in the photodegradation method, a special equipment is required.

As mentioned above, the resist layer (i.e. acid-resistant protective layer and polymer layer) according to the present invention is treated by a chemical hydrolysis method, whereby the resist layer can be removed within a short period of time. The detachment system used in this invention is as follows:

(1) Organophosphoric acid and organosilane can be hydrolysed by means of alkali. Therefore, the purpose of selecting an alkali organic system is the solubility of the polymer and the long alkyl chain as well as the hydrolysis of P—O, Si—O bonds. The alkali-organic solution is based on a salt of an alkali metal (sodium or potassium hydroxide), dissolved in an alcohol (ethanol, 2-propanol, 1-butanol, isobutanol, 2-butanol etc.). The concentration of the solution ranges from 1% to 30% weight/weight (typically, 20%). In order to accelerate the rate of the hydrolysis reaction, the temperature is increased to a range of between 25 and 80° C. (typically, 60° C.).

(2) HF/H₂O (1%), H₂O₂ (0.5-2%)/HF (0.5-3%), HCl/H₂O (1-5%) and ultrasonic treatment were used alone or in combination so as to detach the residue from the metal surface.

In the present invention, polymer substances and SAMs of the acid-resistant protective layer are easily and precisely removed from the finished PCBs by the above methods without etching the subjacent metal, in particular copper and copper alloys.

Since the subject invention has been described in general, it may be further understood with reference to certain special examples which are provided herein for illustrative purposes only and are not to be considered as restrictive.

### EXAMPLE A

Copper-plated PCB blanks are cleaned in 20% phosphoric acid solution at room temperature for 5 min, rinsed in water and dried in a furnace at 100° C. for 5 min, so as to form a hydrophilic surface. The PCB blanks are then immersed for 15 min in a 1.5% 6-mercapto-1-hexanol-ethanol solution at room temperature, rinsed with pure ethanol and then dried in a furnace at 100° C. for 5 min.

Then, by immersing the carriers in 3% octadecyl trichlorosilane-cyclohexane solution at room temperature for 15 min and subsequently placing the carriers into a furnace for hardening at 120° C. for 10 min, a further monolayer is created and thickened by repeating the above process. The PCB blanks are then wet-hardened for several hours at room temperature in a highly moist atmosphere (more than 85% atmospheric humidity). The thus-coated PCB blanks are then immersion-coated in a 3% polysilane-co-polyacrylate base solution (pH=9), then immersion-coated in a 3% polysilane-co-polyacrylate ethanol solution, then dried in a furnace at 120° C. for 15 min.

Since this is only a test, patterning by means of a laser was not carried out, but the coated PCB blanks were etched with a strong acid etching solution (HCl—CuCl₂-CuCl) and then treated with a (NaOH/2 propanol 20%) solution at 60° C. for 5 min. The hydrolysis method can be accelerated by immersion in an ultrasonic bath. The inorganic and organic impurities or residues, respectively, are removed from the metal surface by using an HF/H₂O (1%) and HCl/H₂O (5%) acid solution. Then the PCB blanks are rinsed with water and dried in a furnace or in hot air. By this, a very clean and structured copper-plated surface was again obtained on the PCB blanks.

### EXAMPLE B

Copper-plated PCB blanks are cleaned by removing the natural oxide by immersion in a diluted HNO₃ solution (10% in deionized water) for 5 min. Then, after repeated cleaning with water and isopropyl alcohol, the PCB blanks are dried in a flow of nitrogen gas so as to form a hydrophilic surface.

The first monolayer is then formed by immersion of the freshly cleaned PCB blank in a 3% solution of octadecyl-trichlorosilane, dissolved in hexadecan, at room temperature for 15 min. Die PCB blanks provided with a first monolayer are hardened in a furnace for 10 min at 120° C., and then the process is repeated. The two-fold coating generates a homogenous film on the surface of the PCB blanks. The PCB blanks are then wet-hardened for one hour in a high humidity box (moisture of more than 85% atmospheric humidity).

The coated PCB blanks are immersion-coated in 3% poly(styrene-alt-maleic acid), sodium salt solution (pH=9) and then dried in a furnace at 120° C. for 15 min.

### EXAMPLE C

Copper-plated PCB blanks are immersed in 4N HCl solution for 5 min. The PCB blanks are then rinsed with water and dried in a furnace for a short time at 80° C. The clean PCB blanks can be wetted with water, demonstrating a hydrophilic surface. The cleaning process is carried out less than 1 h before the first monolayer is produced so as to minimize impurities. Before the coating, the PCB blanks are stored in a chamber with a controlled relative humidity of 55%.

The cleaned PCB blanks are then immersed in a 3% 1-octadecanethiol/ethanol solution at room temperature for 15 min, rinsed with pure ethanol and then dried in a furnace at 100° C. for 5 min. The coating process can be repeated any number of times.

The coated PCB blanks are then immersion-coated in 3% polystyrene methacrylate-terminated cyclohexane solution and dried in a furnace at 120° C. for 15 min.

### EXAMPLE D

Copper-plated PCB blanks are cleaned in 20% phosphoric acid solution at room temperature for 5 min, rinsed in water and dried in a furnace at 100° C. for 5 min, so as to form a hydrophilic surface. The pretreated PCB blanks were then immersed in a 1.5% 11-mercapto-undecyl-acid ethanol solution at room temperature for 15 min, rinsed with pure ethanol and then dried in a furnace at 100° C. for 5 min.

Then immersion of the monolayer-provided PCB blanks in 3% octadecyl-trichlorosilane-cyclohexane-solution at room temperature for 15 min and subsequent placing of the PCB blanks in a furnace for hardening at 120° C. for 10 min and repeating of the above process yields two further monolayers. The coated PCB blanks are wet-hardened in a highly moist atmosphere (more than 85% atmospheric humidity) for several hours at room temperature.

The coated PCB blanks are then immersion-coated in 3% polysilane-co-polyacrylate base solution (pH=9), then immersion-coated in 3% polysilane-co-polyacrylate-ethanol solution, then dried in a furnace at 120° C. for 15 min.

Since this is a only test, patterning by means of a laser is not performed, but the coated PCB blanks are etched with a strong acid etching solution (HCl—CuCl₂—CuCl) and then treated with a (NaOH/2-propanol 20%) solution at 60° C. for 5 min. The hydrolysis method can be accelerated by immersion in an ultrasonic bath. The inorganic and organic impurities or residues, respectively, are removed from the metal surface by using an HF/H₂O (1%) and HCl/H₂O (5%) acid solution. Then the PCB blanks are rinsed with water and dried in a furnace or in hot air. By this, a very clean and structured copper-plated surface was again obtained on the PCB blanks.

### References

U.S. Pat. No. 4,622,097, Minoru Tsukagoshi, Takuo Nakayama, Masahiko Minagawa, Shuji Yoshida.
U.S. Pat 6,297,169, Pawitter J. S. Mangat, C. Joseph Mogab, Kevin D. Cummings, Allison M. Fisher.
JP-63/005591 A, Hata Hajime, Kinoshita Masashi, Kamagata Kazuo.
JP-10/060207 A, Nishiguchi Hiroshi, Watanabe Toshio, Kitada Akira.
EP-0 364 132 A, Susumu Matsubara, Shuji Yoshida, Masahiko Minagawa, Daikichi Tachibana.
DE-19 944 908 A, Guggemos Micheal, Kohnle Franz, Kodama Hiroki.
G. Kane Jennings, Jeffrey C. Munro and Paul E. Laibinis, Adv. Mat., 1999, (11) 1000.
J. Sagiv, J. Am. Chem. Soc. 1980 (102) 92-98.
Rye, R. R.; Nelson, G. C.; Dugger, M. T. Langmuir, 1997, 13, 2965-2972.
W. T. S. Huck, L. Yan, A. Stroock, R. Haag and G. M. Whitesides, Langmuir, 1999 (15) 6862.
L. C. F. Blackman and M. J. S. Dewar, J. Chem. Soc., 1957, 171.
S. Fuji, K. Kobayashi in comptes Rendus 2eme Symposium Europeen sur les Inhibiteurs de Corrosion, p. 829, Universita Gegli Studi di Ferrara, Ferrara, Italy (1966).
P. E. Laibinis, G. M. Whitesides, J. Am. Chem. Soc. 114 (1992) 9022.
G. K. Jennings, J. C. Munro, P. E. Laibinis Adv. Mater. 11 (1999) 1000.
M. Itoh, H. Nishihara, K. Aramaki, J. Electrochem. Soc, 142 (1995) 3696.
M. Ishibashi, M. Itoh, H. Nishihara, K. Aramaki, Electrochimca Acta, 41 (1996) 241.
R. Haneda, H. Nishihara and K. Aramaki, J. Electrochem. Soc. 144 (1997) 1215.
Y. T. Tao and M. T. Lee, Thin Solid Films, 244 (1994) 810.
G. K. Rowe and S. E. Creager, Langmuir, 10 (1994) 1186.
Z. T. Kim, R. L. McCarley and A. J. Bard, Langmuir, 9 (1993) 1941.
F. Beck, R. Michaelis, F. Schloten and B. Zinger, Electrochim. Acta, 39 (1994) 224.
V. Brusic, M. Angelopulos and T. Graham, J. Electrochem. Soc., 144 (1997) 436.
R. A. Kurbanova, R. Mirzaoglu, S. Kurbannov, I. Karatas, V. Pamuk, E. Ozcan, A. Okudan, E. Guler, J. Adhes. Sci. Technol., 11 (1997) 105
T. G. Stange, R. Mathew, D. F. Evans, W. A. Hendrickson, Langmuir, 8 (1992) 920.
H. G. Hong, T. E. Mallouk, Langmuir, 7 (1991) 2362.
H. C. Yang, K. Aoki, H. G. Hong, D. D. Sackett, M. F. Arendt, S. L. Yau, C. M. Bell and T. E. Mallouk, J. Am. Chem. Soc., 115 (1993) 11855.
S. Ren and D. Barkey, J. Electrochem. Soc., 39 (1992) 1021.
V. Brusic, M. Angelopulos and T. Graham, J. Electrochem. Soc., 144 (1997) 436.
R. J. Racicot, S. C. Yang and R. Brown, Mater. Res. Soc. Symp., 458 (1997) 415.
J. G. Van Alsten, Langmuir, 15 (1999) 7605.
M. Aslam, K. Bandyopadhyay, K. Vijayamohanan, K. Lakshminarayanan, J. Colloid interface Sci., 234 (2001) 410.
Y. Umemura, K. I. Tanaka, A. Ymagishi, J. Chem. Soc, Chem. Commun. 1992, 67.
M. D. Porter, T. B. Bright, D. L. Allara, C. E. D. Chidsey, J. Am. Chem. Soc. 109 (1987) 3559. W. T. S. Huck, L. Yan, A. Stroock, R. Haag and G. M. Whitesides, Langrmuir, 15 (20) 6862.

1. A PCB blank comprising an acid-resistant protective film, characterized in that the acid-resistant protective film is made up of at least 2 layers which are chemically interconnected, and chemically connected to the metallic surface of the PCB blank, respectively.

2. A PCB blank according to claim 1, characterized in that the protective film has a thickness of less than 20 μm more preferred, less than 10 μm, and most preferred, less than 4 μm.

3. A PCB blank according to claim 1, characterized in that the at least 2 layers of the protective film are each formed by a compound of the general formula
W(R)Y
wherein
W represents —SH, —Si(X)₃, —Si(OR)X₂, —Si(OR)₂X, —Si(OR)₃, —COOH, —PO₃H₂;
R represents alkyl (—CₙH₂ₙ—), optionally substituted with one or more X and/or OH and straight-chain, branched or cyclic with straight-chain alkyl portion, or an aromatic group, preferably substituted by one or more X and/or —OH, and n=2 to 32,
X represents fluorine, chlorine, bromine or iodine, and
Y represents —OH, COOH, —PO₃H₂.

4. A PCB blank according to claim 3, characterized in that n in the indicated general formula means an integer of from 10 to 22.

5. A PCB blank according to claim 1, characterized in that the first layer of the protective film is formed by a compound of the general formula
W(R)Y
wherein W, R, X, n and Y are as defined above, on which layer at least one further layer is deposited which is formed by a compound of the general formula
Z(R)L
wherein:
Z represents Si(OR₂)₂X, —Si(OR₂)X₂, —SiX₃, —PO₃H₂,
L represents —OH, —COOH, —OCH₃, —OR, —CH₃, —CH=CH₂, —COOCH₃, —COOR, —CONH₂, and
R, X and n are as defined above.

6. A PCB blank according to claim 5, characterized in that n in the above-indicated general formulae preferably is each independently an integer of from 10 to 22.

7. A PCB blank according to claim 1, characterized in that the acid-resistant protective film of the PCB blank additionally comprises an organo-soluble or alkali-soluble polymer as the uppermost, or cover layer, respectively.

8. A method for coating PCB blanks with an acid-resistant protective film which is made up of at least 2 layers, comprising the following steps:
a) optionally pre-cleaning, drying, activating and/or surface treating the PCB blank,
b) forming a first monolayer on the metal surface of the PCB blank by applying a compound of the general formula
W(R)Y
wherein W, R, X, n and Y are as defined above,
c) forming at least one further monolayer on the first monolayer of the PCB blank by applying either
c)1) a compound of the general formula
W(R)Y
wherein W, R, X, n and Y are as defined above, or
c)2) a compound of the general formula
Z(R)L
wherein
Z, R, X, n and L are as defined above,
d) optionally repeating step c) several times, and
e) optionally forming a cover layer from an organo-soluble or alkali-soluble polymer on the uppermost monolayer of the PCB blank.

9. A method according to claim 8, characterized in that n in the above-indicated general formulae is each independently an integer of from 10 to 22.

10. A method according to claim 8, characterized in that the compounds for providing the individual monolayers are applied in solution.

11. A method according to claim 10, characterized in that the application of the compounds for providing the individual monolayers is effected by immersing the PCB blank in corresponding solutions of said compounds.
